(19) United States
(12) Patent Application Publication
(10) Pub. No.: US 2004/0000689 A1
(43) Pub. Date: Jan. 1, 2004

(54) Dual-bit MONOS/SONOS memory structure with non-continuous floating gate

(76) Inventors: Erh-Kun Lai, Taichung (TW); Chien-Hung Liu, Taipei (TW); Shou Wei Huang, Keelung (TW); Shyi Shuh Pan, Kaohsiung (TW); Ying Tzoo Chen, Kaohsiung (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/183,528

(22) Filed: Jun. 28, 2002

(51) Int. Cl. H01L 29/788

(52) U.S. Cl. 257/315

(57) ABSTRACT

The present invention generally relates to provide a dual-bit metal oxide nitride oxide semiconductor (MONOS)/semiconductor oxide nitride oxide semiconductor (SONOS) memory structure which is provided with a non-continuous floating gate. In a single memory device, the present invention utilizes a non-continuous floating gate for using as the dual-point electric charge storing unit. However, these two electric charge storing points are controlled by the source and the drain of the device. Utilizing a memory storing two bits can increase the memory content. Furthermore, electric charges stored in these two bits do not cross talk to each other so as the present invention can improve and enhance the reliability of the memory device.

### BACKGROUND OF THE INVENTION

1. Field of the Invention

The present invention generally relates to an improved structure of the metal oxide nitride oxide semiconductor (MONOS)/semiconductor oxide nitride oxide semiconductor (SONOS), and more particularly relates to a memory structure which is utilizing a non-continuous oxide nitride oxide (ONO) as the floating gate to configure as the flash memory, such as the dual-bit memory MONOS/SONOS structure.

2. Description of the Prior Art

In view of the quick development of the computer products, the electrically erasable programmable read only memory (EEPROM) is the extensively used memory device for current IT electronics product. However, the conventional EEPROM has the disadvantage of lower access speed. According to the advancement of the manufacturing technology, the EEPROM with higher access speed has already developed, which is so-called the flash memory, to overcome the disadvantage of the prior memory.

Basically, the conventional flash memory is a non-voltaic memory utilizing a floating gate transistor as a base, such as shown in the FIG. 1. Each memory cell of the flash memory is formed by respectively forming a source 12 and a drain 14 in a semiconductor substrate 10; then forming a structure sequentially composed of an oxide layer 16, a nitride layer 18, and an oxide layer 20, wherein the structure is called the ONO structure 22 to use as the floating gate for storing electric charge; and provided with a control gate 24 on the ONO structure 22 for controlling the data access.

However, the memory status of the flash memory is depended on the concentration of the electric charge and the operation method is depended on the technology of injecting or removing electric charge from the floating gate. Hence, in the programming step of writing in data, a high voltage is applied on the control gate 24 so as the hot electron will penetrate the oxide layer 16 to inject into the nitride layer 18 of the floating gate to enhance the critical voltage to write in data. In the erasing step, a voltage is applied on the control gate 24 and the drain 14 to use the so-called hot hole erasing technology to inject the hot hole into the nitride layer 18 of the floating gate to erase data.

Obviously, in the MONOS/SONOS memory structure of the flash memory mentioned above, each memory unit can store only a bit or two bits. However, the electric charges stored in two bits will cross talk to each so as the reliability of the device can not achieve as the desire. Hence, the main spirit of the present invention is to provide a dual-bit MONOS/SONOS memory structure with a non-continuous ONO floating gate, and then some disadvantages of well-known technology are overcome.

### SUMMARY OF THE INVENTION

The primary object of the invention is to provide to a dual-bit metal oxide nitride oxide semiconductor (MONOS)/semiconductor oxide nitride oxide semiconductor (SONOS) memory structure provided with a non-continuous oxide nitride oxide (ONO) the floating gate, wherein each cell of the MONOS/SONOS memory provides two non-continuous floating gates to use as the dual-point electric charge storing region so as to enhance the memory content up twice as the conventional memory content. Furthermore, these two electric charge storing points can be respectively controlled by the arrangement of the source, the drain, and the gate of the device.

Another object of the invention is to provide a structure of the MONOS/SONOS memory which each memory cell of the MONOS/SONOS memory can store two electric charges and electric charges of these two bits do not cross talk to each other so as the present invention can improve and enhance the reliability of the memory device.

In order to achieve previous objects, the present invention forms two N⁺ type ion-implanting regions in a P type semiconductor substrate to use as a source and a drain. Then, a tunneling channel dielectric layer is positioned overlaying the semiconductor substrate between the source and the drain. Two separating floating gates are respectively positioned on the tunneling channel dielectric layer, wherein each of these floating gates is composed of a nitride layer and an oxide layer. A control gate is positioned stacking on a surface of these floating gates and on an exposed surface of the tunneling channel dielectric layer in the central region of these two floating gates, wherein the control gate is used to control the channel on or off.

Other aspects, features, and advantages of the present invention will become apparent as the invention becomes better understood by reading the following description in conjunction with the accompanying drawings.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic representation structure of a flash memory structure, in accordance with prior techniques; and

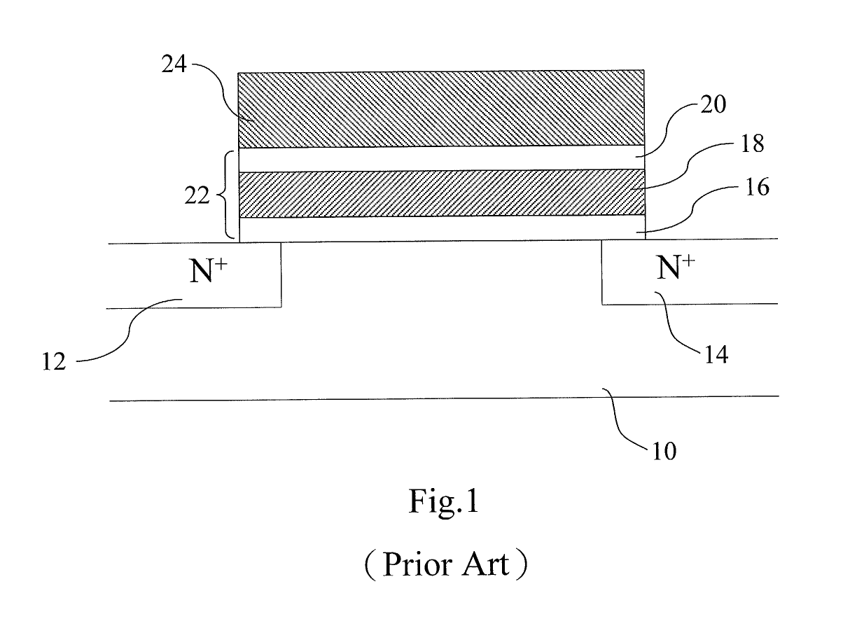

FIG. 2 is a schematic representation structure of the dual-bit memory MONOS/SONOS structure, in accordance with the present invention.

### DESCRIPTION OF THE PREFERRED EMBODIMENT

The primary feature of the present invention is to utilize a non-continuous oxide nitride oxide (ONO) floating gate to configure as the dual-bit memory MONOS/SONOS memory structure. Each memory cell of the present MONOS/SONOS memory structure at least provides with two floating gates as the electric charge storing region, so as the present invention can enhance the memory content up twice as the conventional memory content without increasing the density per memory unit. The following description discloses a flash memory structure with a P type semiconductor substrate to illustrate the structure and advantages of the dual-bit memory MONOS/SONOS memory structure of the present invention.

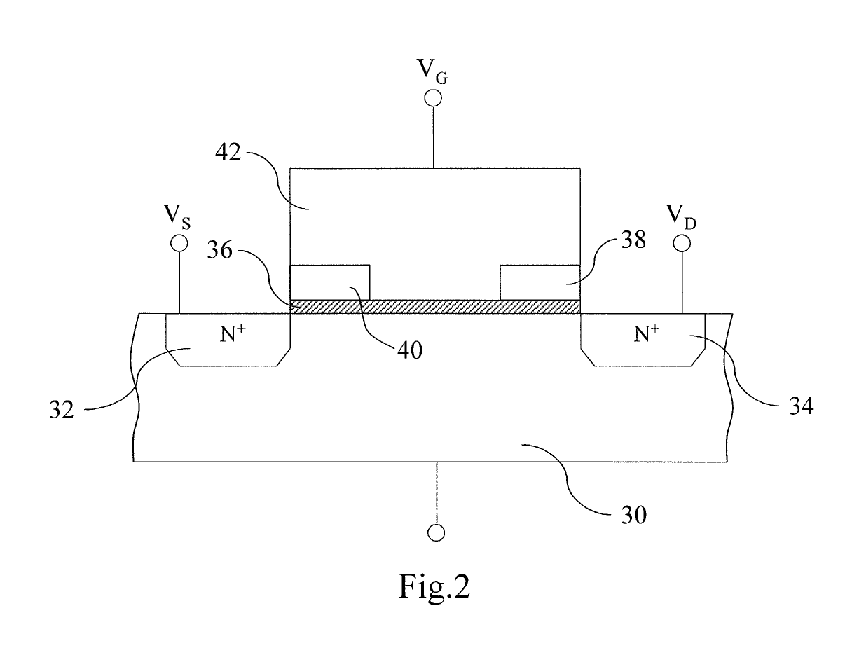

Referring to the FIG. 2, a single memory cell structure of the dual-bit flash memory is disclosed. A P type semiconductor substrate 30 is ion-implanted to form two N⁺ type ion-implanting regions to respectively use as a source 32 and a drain 34 of the memory cell. Then, a tunneling channel dielectric layer 36 is positioned overlaying the P type semiconductor substrate 30 between the source 32 and the drain 34. Usually, the tunneling channel dielectric layer 36 is made of the oxide layer. Besides, there are two separating floating gates positioned on a surface of the tunneling channel dielectric layer 36 for storing electric charge. Each of these floating gates 38, 40 is composed of a nitride layer (usually a silicon nitride layer) and an oxide layer, which is so-call nitride-oxide (NO) film. These two floating gates 38, 40 are electrically isolated with the source 32 and the drain 34 by the tunneling channel dielectric layer 36. Furthermore, a control gate 42 is positioned stacking on a surface of these floating gates 38, 40 and on an exposed surface of the tunneling channel dielectric layer 36 in the central region of these two floating gates, wherein the control gate is made of the high-implanted polysilicon gate and using for read data. In the present invention, the central region of the channel region between the control gate 42 and the P type semiconductor substrate 30 has a region without floating gates 38, 40.

By controlling the difference of applied voltage between the control gate 42, the source 32, and the drain 34, a channel and hot electrons are formed in a region which is in the P type semiconductor substrate 30 under floating gates 38, 40 and between the source 32 and the drain 34, so as it can perform the operation of programming, erasing, and read of the dual-bit flash memory. Owing to floating gates 38,40 of the mentioned dual-bit flash memory are isolated as two electric charge storing units, so stored electric charges of two bits do not cross talk each other so as the present invention can improve and enhance the reliability of the memory device.

In the present invention, a top dielectric layer is positioned between the control gate 42 and floating gates 38, 40 to separate the control gate 42 and floating gates 38, 40. However, the P type semiconductor substrate can be replaced with the N type semiconductor substrate, so the ion-implanting region of the source and the drain in the memory cell respectively change as the P⁺ ion-implant. Other structure and its related position are same as the mentioned above and there is no redundant description in the following.

The following description will detailed described the operation method of the dual-bit MONOS/SONOS memory cell structure of the present invention, such as shown in the FIG. 2 to explain the operation method of the memory cell. The operation method is to respectively apply a source voltage (V_{S}), a drain voltage (V_{D}), and a gate voltage (V_{G}) on the source 32, the drain 34 and the control gate 42 of the flash memory cell to perform the programming step, the erasing step, and the read step of the memory cell.

When the right-bit is performed the programming step, the gate voltage applied on the control gate 42 is a positive voltage V_{G}=10 V, the applied voltage of the drain 34 is V_{D}=5 V, and the applied voltage of the source 32 is V_{S}=0 V. Wherein the P type semiconductor substrate 30 is in grounded status, so as the generated hot electrons close to the channel of the drain 34 are injected into the floating gate 38 of the right bit by hot electron injection method.

When the right-bit is performed the erasing step, the gate voltage applied on the control gate 42 is V_{G=}3 V, the applied voltage of the drain 34 is V_{D=}5 V. Wherein the source 32 is in floating status and the P type semiconductor substrate 30 is in grounded status, so as the hot holes are injected into the floating gate 38 of the right bit to achieve the purpose of erasing data by band to band hot hole erase method.

When the right-bit is performed the read step, the applied voltage of the control gate 42 is V_{G}=3 V, the working voltage of the drain 34 is V_{D}=0 V, and the applied voltage of the source 32 is V_{S}=5 V. Wherein the P type semiconductor substrate 30 is still in grounded status so as to complete the read step of the floating gate 38 of the right bit of the flash memory cell.

In the programming step, the erasing step, and the read step mentioned above, it takes the right bit for explanation of the operation method of the present invention. However, about the operation method of the left bit, it only needs to maintain the gate applied voltage V_{G} in original status and exchange the source voltage Vs and the drain voltage V_{D}, and then can achieve the operation of the programming step, the erasing step, and the read step of the left bit.

Hence, the present invention uses the two non-continuous floating gates as the dual-point electric charge storing region so as to enhance the memory content up twice as the conventional memory content. Furthermore, these two electric charge storing points can be respectively controlled by the arrangement of the source, the drain, and the gate of the device to control the operation of the right bit or left bit.

Of course, it is to be understood that the invention described herein is not intended to be exhaustive or to limit the invention to he precise from disclosed. The description was selected to best explain the principles of the invention and practical application of these principles to enable others skilled in the art to best utilize the invention in various embodiments and modifications as are suited to the particular use contemplated. It is intended that the scope of the invention not to be limited by the specification, but be defined by the claim set forth below.

What is claimed is:

1. A dual-bit metal oxide nitride oxide semiconductor (MONOS)/semiconductor oxide nitride oxide semiconductor (SONOS) memory structure with a non-continuous floating gate, said memory structure comprising:
a semiconductor substrate, wherein a plurality of ion-implanting region therein to respectively use as a source and a drain;
a tunneling channel dielectric layer positioned overlaying a surface of said semiconductor substrate between said source and said drain;
at least two floating gates respectively positioned on said tunneling channel dielectric layer, wherein each of said floating gates is composed of a nitride layer and an oxide layer; and
a control gate positioned stacking on a surface of said floating gates and on an exposed surface of said tunneling channel dielectric layer in central region of said two floating gates, wherein said control gate is used to control the channel on or off.

2. The dual-bit MONOS/SONOS memory structure according to claim 1, wherein said semiconductor substrate is made of by selected by the group of a P type semiconductor and a N type semiconductor.

3. The dual-bit MONOS/SONOS memory structure according to claim 1, wherein said ion-implanting region for said source and said drain is implanted a same type ion which is selected by the group of a P type ion and a N type ion.

4. The dual-bit MONOS/SONOS memory structure according to claim 1, further comprises a top dielectric layer positioned between said control gates and said floating gates.
